(19) United States
(12) Patent Application Publication
(10) Pub. No.: US 2025/0309566 A1
(43) Pub. Date: Oct. 2, 2025

(54) ANTENNA MODULE

(71) Applicant: TDK Corporation, Tokyo (JP)

(72) Inventors: Toshiyuki ABE, Tokyo (JP); Kazutoshi TSUYUTANI, Tokyo (JP); Kazuhiro YOSHIKAWA, Tokyo (JP); Hiroyuki NISHIOKA, Tokyo (JP); Naoyuki ISHIKAWA, Tokyo (JP)

(21) Appl. No.: 18/855,768

(22) PCT Filed: Feb. 6, 2023
(86) PCT No.: PCT/JP2023/003698

§ 371 Date: Oct. 10, 2024

(30) Foreign Application Priority Data
Apr. 15, 2022 (JP) 2022-067461

(51) Int. Cl. H01Q 23/00; H01Q 1/24; H05K 3/46

(52) U.S. Cl. CPC H01Q 23/00; H01Q 1/24; H05K 3/46

(57) ABSTRACT

To provide an antenna module incorporating an electronic component such as an RFIC. An antenna module includes a core substrate, an outermost insulating layer, and a resin layer provided between the core substrate and the outermost insulating layer and embedding therein an RFIC. The core substrate has a core layer, insulating layers and sandwiching the core layer, a through hole conductor connecting conductor layers to, an antenna layer, and feeding patterns and, a via conductor connecting the feeding pattern and a feeding pattern, and a via conductor connecting an antenna pattern and the feeding pattern. The resin layer has a conductor layer connected to the RFIC. The conductor layer is larger in thickness than the conductor layer, which makes cracks or disconnection unlikely to occur in the conductor layer while achieving fine pitch of the conductor layer.

### TECHNICAL FIELD

The present invention relates to an antenna module and, more particularly, to an antenna module incorporating an electronic component such as an RFIC.

### BACKGROUND ART

Patent Documents 1 and 2 disclose antenna modules provided with an antenna and an RFIC connected thereto.

### CITATION LIST

### Patent Document

[Patent Document 1] JP 2018-032890A
[Patent Document 2] JP 2021-114655A

### DISCLOSURE OF THE INVENTION

### Problem to be Solved by the Invention

However, the antenna modules disclosed in Patent Documents 1 and 2 have a structure in which the antenna and RFIC are mounted respectively on one surface and the other surface of a substrate, so that connection to external circuits is not easy. In addition, when a conductor pattern to be formed on the other surface of the substrate is made thin for fine pitch, the conductor pattern is likely to undergo cracks or disconnection after the antenna module is mounted on a motherboard.

It is therefore an object of the present disclosure to provide an antenna module incorporating an electronic component such as an RFIC.

### Means for Solving the Problem

An antenna module according to the present disclosure includes: a core substrate; an outermost insulating layer obtained by impregnating a core material with resin; at least one resin layer provided between the core substrate and the outermost insulating layer; and an electronic component embedded in the resin layer. The main surface of the electronic component on which a terminal electrode is provided is positioned on the outermost insulating layer side. The core substrate has a first conductor layer on its one surface side positioned at the boundary with the resin layer and an antenna layer provided on its other surface side opposite to the one surface side and including an antenna pattern. The resin layer has a second conductor layer provided on its surface side positioned at the boundary with the outermost insulating layer and including a conductor pattern connected to the terminal electrode of the electronic component. The first conductor layer is larger in thickness than the second conductor layer.

According to the technology of the present disclosure, the antenna pattern and the electronic component such as an RFIC are incorporated in a substrate having a multilayer wiring structure, thus facilitating connection to an external circuit. Further, the resin layer embedding therein the electronic component such as an RFIC is sandwiched between the core substrate and the outermost insulating layer, making it possible to prevent warpage. Furthermore, there is no necessity of forming, between the electronic component and the antenna pattern, a fine pattern to be connected to the terminal electrode of the electronic component, making it possible to prevent interference between various conductor patterns connected to the electronic component and the antenna pattern. Furthermore, the first conductor layer is larger in thickness than the second conductor layer, which makes cracks or disconnection unlikely to occur in the first conductor layer after the antenna module is mounted on a motherboard while achieving fine pitch of the second conductor layer to be connected to the terminal electrode of the electronic component.

In the present disclosure, the core substrate may have: a core layer having a first main surface which is positioned on the resin layer side and on which a third conductor layer is formed and a second main surface which is positioned on a side opposite to the first main surface and on which a fourth conductor layer is formed; a first insulating layer covering the first main surface of the core layer and obtained by impregnating a core material with resin; a second insulating layer covering the second main surface of the core layer and obtained by impregnating a core material with resin; a through hole conductor penetrating the core layer and connecting a first feeding pattern included in the third conductor layer and a second feeding pattern included in the fourth conductor pattern; a first via conductor penetrating the first insulating layer and connecting a third feeding pattern included in the first conductor layer and connected to the electronic component and the first feeding pattern; and a second via conductor penetrating the second insulating layer and connecting the antenna pattern and the second feeding pattern. The core layer may be larger in thickness than the first and second insulating layers. The core substrate is thus constituted by the core layer and the insulating layers formed on both surfaces thereof, thus increasing design freedom.

In the present disclosure, the through hole conductor and the first via conductor may be provided so as to overlap the antenna pattern. This makes it possible to connect the third feeding pattern and antenna pattern at the shortest distance.

In the present disclosure, the core layer may be larger in thickness than the electronic component. This can further increase the entire mechanical strength.

In the present disclosure, the third conductor layer further including a first ground pattern provided so as to surround the first feeding pattern and overlapping the antenna pattern, and a second ground pattern included in the first conductor layer may be connected to the first ground pattern through a third via conductor penetrating the first insulating layer. This can achieve high antenna characteristics and prevent interference between the RFIC and the antenna pattern.

In the present disclosure, the first and second via conductors may have a filled-via structure. This can reduce the resistance value of the via conductor and allow stacking of the plurality of via conductors.

In the present disclosure, the core substrate and the outermost insulating layer may be smaller in thermal expansion coefficient than the resin layer. This can effectively prevent warpage.

### Advantageous Effect of the Invention

As described above, according to the technology of the present disclosure, there can be provided an antenna module incorporating an electronic component such as an RFIC.

### BRIEF DESCRIPTION OF THE DRAWINGS

FIG. 1 is a schematic cross-sectional view for explaining the structure of an antenna module 100 according to an embodiment of the technology described herein.

FIG. 2 is a process view for explaining a manufacturing method for the antenna module 100.

FIG. 3 is a process view for explaining a manufacturing method for the antenna module 100.

FIG. 4 is a process view for explaining a manufacturing method for the antenna module 100.

FIG. 5 is a process view for explaining a manufacturing method for the antenna module 100.

FIG. 6 is a process view for explaining a manufacturing method for the antenna module 100.

FIG. 7 is a process view for explaining a manufacturing method for the antenna module 100.

FIG. 8 is a process view for explaining a manufacturing method for the antenna module 100.

FIG. 9 is a process view for explaining a manufacturing method for the antenna module 100.

FIG. 10 is a process view for explaining a manufacturing method for the antenna module 100.

### MODE FOR CARRYING OUT THE INVENTION

Hereinafter, preferred embodiments of the present invention will be described in detail with reference to the accompanying drawings.

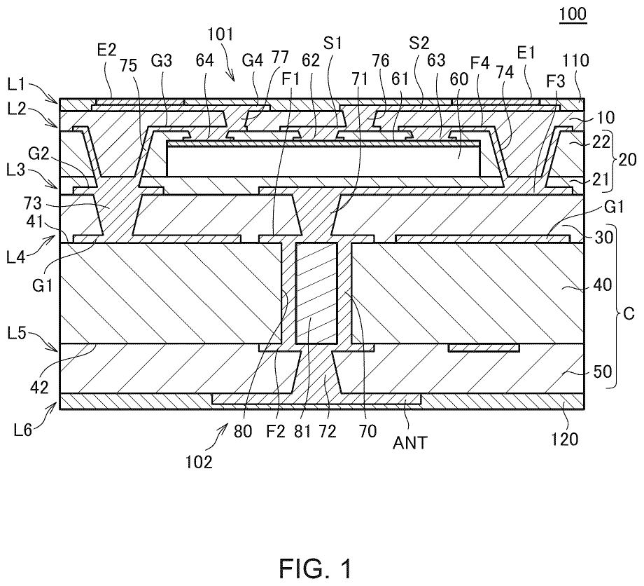

FIG. 1 is a schematic cross-sectional view for explaining the structure of an antenna module 100 according to an embodiment of the technology described herein.

As illustrated in FIG. 1, the antenna module 100 according to the present embodiment incorporates an RFIC 60 and has external terminals E1, E2 and an antenna pattern ANT respectively on one surface 101 and the other surface 102. This allows the antenna module 100 according to the present embodiment not only to be surface-mounted on another substrate such as a motherboard but also to be embedded in the substrate. The surface 101 of the antenna module 100 is covered with a solder resist 110 except for a portion where the external terminals E1 and E2 are exposed. The surface 102 of the antenna module 100 is entirely covered with a solder resist 120, including a portion where the antenna pattern ANT is provided.

The antenna module 100 according to the present embodiment has a structure in which an outermost insulating layer 10, a resin layer 20, and a core substrate C are stacked one on another, and the RFIC 60 is embedded in the resin layer 20. The core substrate C includes a core layer 40 and insulating layers 30 and 50 positioned on both surfaces of the core layer 40. The outermost insulating layer 10, core layer 40, and insulating layers 30 and 50 are each a material obtained by impregnating a core material with resin, whereas the resin layer 20 does not contain a core material which can hinder embedding of the RFIC 60. Thus, the resin layer 20 is larger in thermal expansion coefficient than the outermost insulating layer 10, core layer 40, and insulating layers 30 and 50. However, it is not essential that the resin layer 20 does not contain a core material, but the resin layer 20 may have a structure in which a core material including glass cloth or metal is removed at a portion where the RFIC 60 is embedded.

The core layer 40 is made of a material having high strength, such as an FR4, and is larger in thickness than the outermost insulating layer 10 and insulating layers 30 and 50, as well as the RFIC 60. This ensures mechanical strength of the antenna module 100. The outermost insulating layer 10 and insulating layers 30 and 50 may be made of the same material or different materials. As described above, the core substrate C and outermost insulating layer 10 are made of a material obtained by impregnating a core material with resin and is thus smaller in thermal expansion coefficient than the resin layer 20. Thus, sandwiching the resin layer 20 between the core substrate C and the outermost insulating layer 10 which are smaller in thermal expansion coefficient can prevent the antenna module 100 from being warped when it is made thin.

A conductor layer L4 is provided on one main surface 41 of the core layer 40, and a conductor layer L5 is provided on the other main surface 42 opposite to the main surface 41. The conductor layer L4 includes a feeding pattern F1 and a ground pattern G1 surrounding the feeding pattern F1. The conductor layer L4 is covered with the insulating layer 30. The conductor layer L5 includes a feeding pattern F2 and is covered with the insulating layer 50. The core layer 40 has a through hole conductor 70 formed therein. The through hole conductor 70 is a cylindrical conductor pattern formed on the inner wall of a through hole 80 penetrating the core layer 40 and connects the feeding patterns F1 and F2. The area surrounded by the through hole conductor 70 is filled with an insulating resin 81.

An antenna layer L6 is provided on the surface of the insulating layer 50 that is positioned on the side opposite the main surface 42 of the core layer 40. The antenna layer L6 includes the above-mentioned antenna pattern ANT. The antenna pattern ANT is connected to the feeding pattern F2 included in the conductor layer L5 through a via conductor 72 penetrating the insulating layer 50. The conductor layer L5 positioned immediately below the antenna layer L6 has a residual copper rate of as low as about 10% since most conductor patterns are removed therefrom, whereas the conductor layer L4 having the feeding pattern F1 and ground pattern G1 has a residual copper rate of about 50%. Such a difference in the residual copper rate enhances antenna characteristics and prevents warpage.

A conductor layer L3 is provided on the surface of the insulating layer 30 positioned on the side opposite the main surface 41 of the core layer 40. The conductor layer L3 includes a feeding pattern F3 and a ground pattern G2. The feeding pattern F3 is connected to the feeding pattern F1 included in the conductor layer L4 through a via conductor 71 penetrating the insulating layer 30. The ground pattern G2 is connected to the ground pattern G1 included in the conductor layer L4 through a via conductor 73 penetrating the insulating layer 30. The ground pattern G1 is provided so as to surround the feeding pattern F1 and to have an overlap with the antenna pattern ANT. This allows the antenna pattern ANT to function as a radiation conductor of a patch antenna. However, an antenna to be incorporated in the antenna module 100 according to the present embodiment need not necessarily be a patch antenna but may be an antenna of another type, such as an inverted-F antenna. The through hole conductor 70 and via conductors 71 and 72 are provided so as to overlap the antenna pattern ANT, whereby the wiring distance from the feeding pattern F3 to the antenna pattern ANT is reduced.

The resin layer 20 is provided on the core substrate C. The resin layer 20 is formed of stacked resin layers 21 and 22, and the RFIC 60 is embedded in the resin layer 22. The RFIC 60 is embedded such that the main surface thereof on which terminal electrodes are provided faces the outermost insulating layer 10. The main surface of the RFIC 60 is covered with a re-wiring layer 61, and terminal electrodes 62 to 64 are exposed to the surface of the re-wiring layer 61. The terminal electrode 62 is a signal terminal connected to an external circuit, the terminal electrode 63 is an antenna terminal connected to the antenna pattern ANT, and the terminal electrode 64 is a ground terminal supplied with a ground potential. Although not shown in FIG. 1, other terminals such as a power supply terminal supplied with a power supply potential are provided.

A conductor layer L2 is provided on the surface of the resin layer 20 positioned on the side opposite the core substrate C (positioned at the boundary with the outermost insulating layer 10). The conductor layer L2 includes a signal pattern S1, a feeding pattern F4, and a ground pattern G3 which are connected to the terminal electrodes 62, 63, and 64, respectively. The feeding pattern F4 is connected to the feeding pattern F3 included in the conductor layer L3 through a via conductor 74 penetrating the resin layer 20. The ground pattern G3 is connected to the ground pattern G2 included in the conductor layer L3 through a via conductor 75 penetrating the resin layer 20.

A conductor layer L1 is provided on the surface of the outermost insulating layer 10 positioned on the side opposite the resin layer 20. The conductor layer L1 includes a signal pattern S2 and a ground pattern G4. The signal pattern S2 is connected to the signal pattern S1 included in the conductor layer L2 through a via conductor 76 penetrating the outermost insulating layer 10. The ground pattern G4 is connected to the ground pattern G3 included in the conductor layer L2 through a via conductor 77 penetrating the outermost insulating layer 10. The signal pattern S2 and ground pattern G4 are connected respectively to the external terminals E1 and E2. The external terminal E1 is a signal terminal for exchanging signals with an external circuit. The external terminal E2 is a ground terminal supplied with a ground potential from outside.

A conductor pattern constituting the conductor layer L3 is larger in conductor thickness than a conductor pattern constituting the conductor layer L2. This can prevent disconnection of the conductor layer L3 which is most likely to be applied with stress after the antenna module 100 is mounted on a motherboard or the like while achieving fine pitch of the conductor layer L2 to be connected to the terminal electrodes 62 to 64 of the RFIC 60. That is, the conductor layer L2, which has suppressed thermal shrinkage due to the presence of the RFIC 60 with a small linear expansion coefficient and a motherboard fixed to the module body serving as a restricting layer, has a low risk of disconnection, thus making it possible to reduce the conductor thickness for fine pitch; on the other hand, the conductor layer L3, which is positioned at the boundary between the resin layer 20 and the core substrate C, is in a free state without being restricted and thus has a high risk of disconnection due to thermal shrinkage. Accordingly, by making the thickness of the conductor layer L3 larger than that of the conductor layer L2, it is possible to prevent disconnection and cracks. Further, when the thickness of the conductor layer L3 is sufficiently increased, the feeding pattern F3 is made low in resistance, which in turn improves antenna characteristics. The conductor layers other than the conductor layers L2 and L3 are not particularly limited in conductor thickness; however, by making the conductor thickness of a conductor pattern constituting the conductor layers L1 and L2 smaller than a conductor pattern constituting the conductor layers L3 to L5 and antenna layer L6, it is possible to improve antenna characteristics while reducing the pitch of the conductor pattern connecting the external terminals E1, E2 and the RFIC 60.

As described above, the antenna module 100 according to the present embodiment has the antenna pattern ANT provided on the surface 102 of the substrate with a multilayer wiring structure and the RFIC 60 embedded thereinside, so that it can use the surfaces 101 and 102 as a mounting surface and a radiation surface, respectively. Further, the insulating layers 30 and 50 are provided on the front and back of the core layer 40 to allow the core substrate C to have a multilayer wiring structure, increasing design freedom. Furthermore, the core layer 40 having high strength is larger in thickness than the insulating layers 30 and 50, so that the entire mechanical strength is sufficiently ensured. Still further, the outermost insulating layer 10 positioned on the surface 101 side is made of a material obtained by impregnating a core material with resin, warpage can be prevented. In addition, the via conductors 71 to 73 have a so-called filled-via structure, so that, as illustrated in FIG. 1, no irregularity occurs in the antenna pattern ANT, and the via conductor 75 can be stacked immediately above the via conductor 73.

Further, in the present embodiment, the main surface of the RFIC 60 faces the side opposite the antenna layer L6, thereby eliminating the need to form a fine pattern to be connected to the terminal electrodes 62 to 64 between the RFIC 60 and the antenna pattern ANT. This can prevent interference between various conductor patterns connected to the RFIC 60 and the antenna pattern ANT.

The following describes a manufacturing method for the antenna module 100.

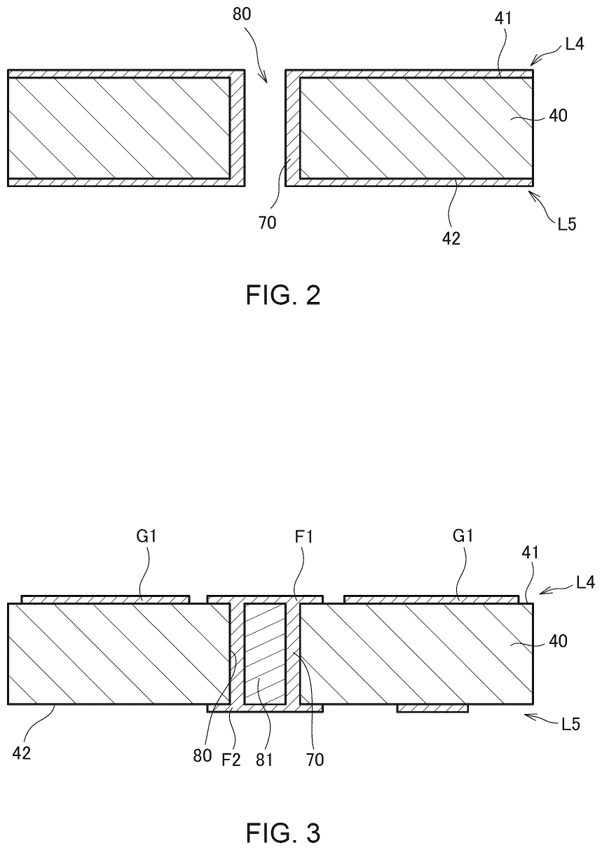

FIGS. 2 to 10 are process views for explaining a manufacturing method for the antenna module 100 according to the present embodiment.

As illustrated in FIG. 2, the core layer 40 having a structure obtained by forming a metal layer, such as a Cu layer, on both surfaces of a core material (e.g., FR4) is prepared, and the through hole 80 penetrating the core layer 40 is formed by drilling or the like. The metal layer provided on the main surface 41 of the core layer 40 constitutes the conductor layer L4, and the metal layer provided on the main surface 42 of the core layer 40 constitutes the conductor layer L5. Then, electrolytic plating or the like is performed to form the through hole conductor 70 on the inner wall of the through hole 80. Subsequently, as illustrated in FIG. 3, the insulating resin 81 is embedded in the through hole 80, and the conductor layers L4 and L5 are patterned, whereby the feeding patterns F1 and F2 and the ground pattern G1 are formed. The feeding patterns F1 and F2 are connected to each other through the through hole conductor 70.

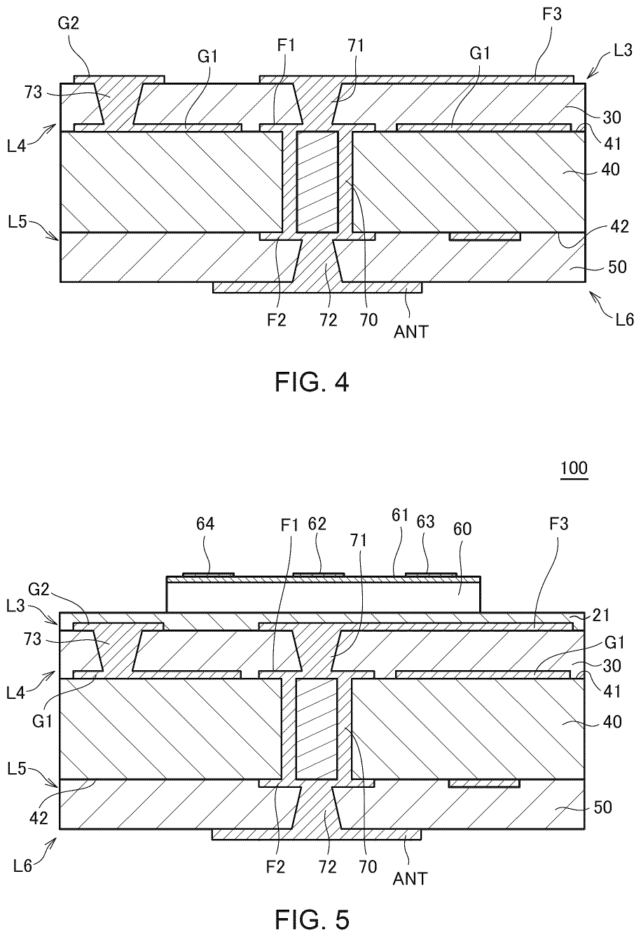

Then, as illustrated in FIG. 4, a prepreg is attached to both surfaces of the core layer 40. In this state, hot press is performed to form the insulating layers 30 and 50. As the prepreg used for making the insulating layers 30 and 50, the same low dielectric material as that for the core layer 40 may be used. Subsequently, after via formation in the insulating layers 30 and 50, seed layer formation, electrolytic plating, and patterning are carried out to thereby form the via conductors 71 to 73, feeding pattern F3, ground pattern G2 and antenna pattern ANT. As a result, the conductor layer L3 is formed on the surface of the insulating layer 30, and the antenna layer L6 is formed on the surface of the insulating layer 50. At this time, it is preferable that the via holes for the via conductors 71 to 73 be substantially entirely filled with a conductor such as Cu so as to make the via conductors 71 to 73 to have a filled-via structure. With this configuration, the surfaces of the via conductors 71 to 73 are maintained flat. Through the process described above, the core substrate C is completed.

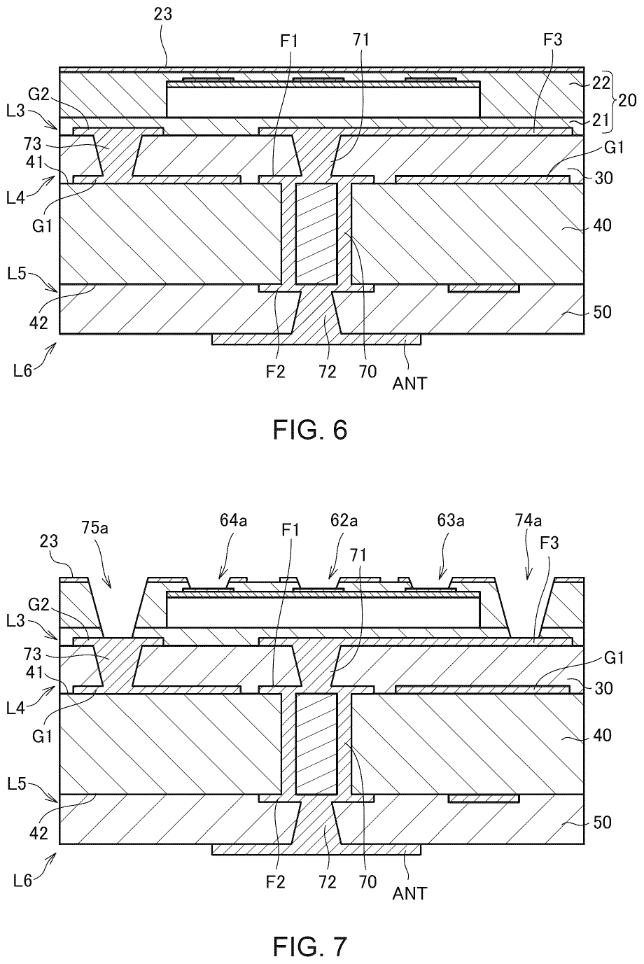

Then, as illustrated in FIG. 5, the resin layer 21 is formed on the surface of the insulating layer 30, and the RFIC 60 is mounted in a face-up manner on the surface That is, the RFIC 60 is mounted of the resin layer 21. such that the terminal electrodes 62 to 64 provided on the RFIC 60 face the side opposite the resin layer 21. Subsequently, as illustrated in FIG. 6, the resin layer 22 having a metal foil 23 made of Cu or the like on its one surface is prepared and stacked on the surface of the resin layer 21 so as to embed therein the RFIC 60. In this state, hot press is performed to integrate the resin layers 21 and 22 to thereby constitute the resin layer 20 embedding therein the RFIC 60. Subsequently, as illustrated in FIG. 7, the metal foil 23 is patterned, and laser machining or blasting is performed using the metal foil 23 as a mask, whereby vias 62a to 64a, 74a, and 75a are formed in the resin layer 20. As a result, the terminal electrodes 62 to 64 of the RFIC 60 are exposed to the bottom parts of the respective vias 62a to 64a, and the feeding pattern F3 and the ground pattern G2 are exposed to the bottom parts of the respective vias 74a and 75a.

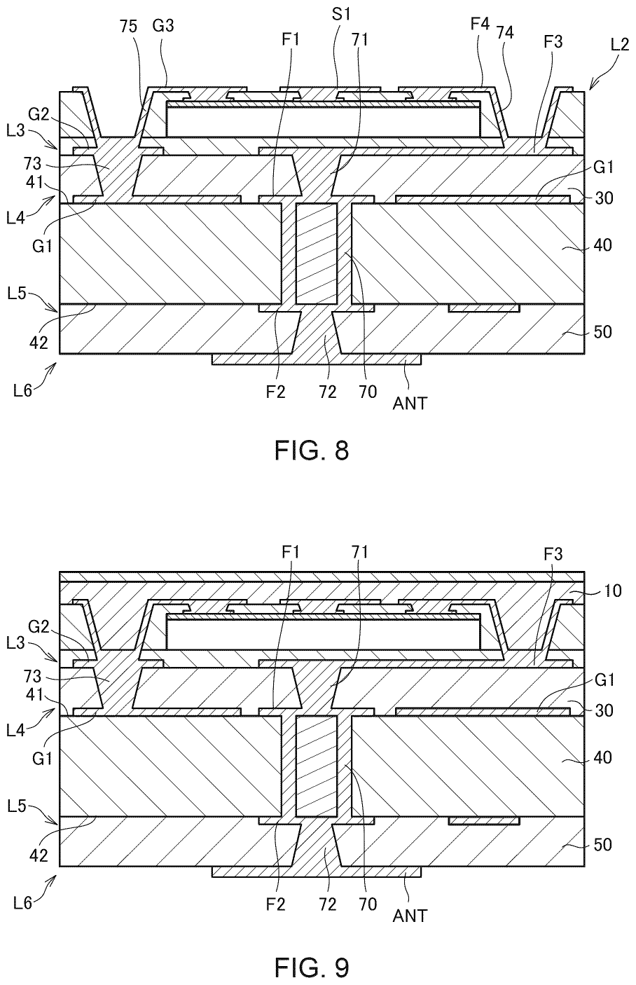

Then, as illustrated in FIG. 8, seed layer formation, electrolytic plating, and patterning are carried out to thereby form the via conductors 74 and 75, signal pattern S1, feeding pattern F4, and ground pattern G3. The via conductors 74 and 75 are connected respectively to the feeding pattern F3 and the ground pattern G2, and the signal pattern S1, feeding pattern F4, and the ground pattern G3 are connected respectively to the terminal electrodes 62, 63, and 64 of the RFIC 60. The via conductors 74 and 75 may have a conformal via structure. As a result, the conductor layer L2 is formed on the surface of the resin layer 20. Subsequently, as illustrated in FIG. 9, a prepreg is attached to the surface of the resin layer 20. In this state, hot press is performed to form the outermost insulating layer 10. The prepreg used for the outermost insulating layer 10 may be the same as that used for the insulating layers 30 and 50.

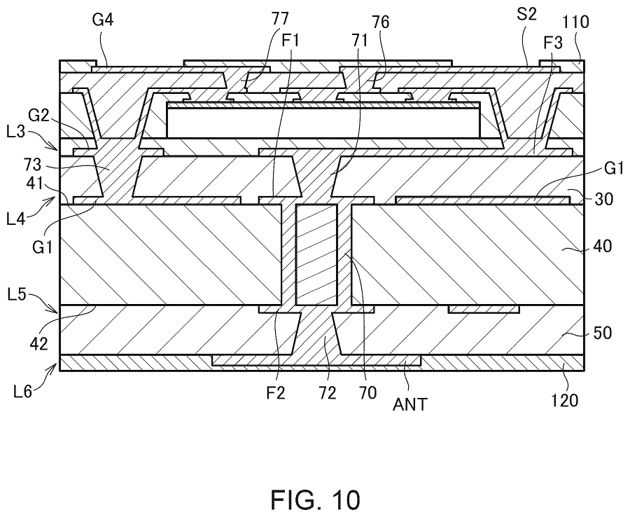

Then, as illustrated in FIG. 10, a via is formed in the outermost insulating layer 10, and seed layer formation, electrolytic plating, and patterning are carried out to form the via conductors 76 and 77, signal pattern S2, and ground pattern G4. As a result, the conductor layer L1 is formed on the surface of the outermost insulating layer 10. After that, the conductor layer L1 is covered with the solder resist 110 so as to partially expose therefrom the signal pattern S2 and ground pattern G4, and the antenna layer L6 is covered with the solder resist 120. Subsequently, the signal pattern S2 and ground pattern G4 exposed from the solder resist 110 are subjected to partial surface treatment to form the external terminals E1 and E2, whereby the antenna module 100 illustrated in FIG. 1 is completed.

As described above, it is possible to manufacture the antenna module 100 according to the present embodiment by stacking the plurality of insulating layers and conductor layers using the core layer 40 as a starting material.

While the preferred embodiment of the present disclosure has been described, the present disclosure is not limited to the above embodiment, and various modifications may be made within the scope of the present disclosure, and all such modifications are included in the present disclosure.

For example, the RFIC 60 is embedded in the resin layer 20 in the above embodiment; however, an electronic component to be embedded in the resin layer is not limited to the RFIC but may be a semiconductor IC chip of another type, such as a CPU, a memory, a sensor, or a power IC, or a passive component, such as a coil or a capacitor.

This application claims the benefit of Japanese Patent Application No. 2022-067461, filed on Apr. 15, 2022, the entire disclosure of which is incorporated by reference herein.

### REFERENCE SIGNS LIST

10 outermost insulating layer
20-22 resin layer
23 metal foil
30, 50 insulating layer
40 core layer
41, 42 main surface of the core layer
60 RFIC
61 re-wiring layer
62-64 terminal electrode
62a-64a, 74a, 75a via
70 through hole conductor
71-77 via conductor
80 through hole
81 insulating resin
100 antenna module
101, 102 surface of antenna module
110, 120 solder resist
ANT antenna pattern
C core substrate
E1, E2 external terminal
F1-F4 feeding pattern
G1-G4 ground pattern
L1-L5 conductor layer
L6 antenna layer
S1, S2 signal pattern

1. An antenna module comprising:
a core substrate;
an outermost insulating layer obtained by impregnating a core material with resin;
at least one resin layer provided between the core substrate and the outermost insulating layer; and
an electronic component embedded in the resin layer,
wherein a main surface of the electronic component on which a terminal electrode is provided is positioned on the outermost insulating layer side,
wherein the core substrate has a first conductor layer on its one surface side positioned at a boundary with the resin layer and an antenna layer provided on its other surface side opposite to the one surface side and including an antenna pattern,
wherein the resin layer has a second conductor layer provided on its surface side positioned at a boundary with the outermost insulating layer and including a conductor pattern connected to the terminal electrode of the electronic component, and
wherein the first conductor layer is larger in thickness than the second conductor layer.

2. The antenna module as claimed in claim 1,
wherein the core substrate has:
a core layer having a first main surface which is positioned on the resin layer side and on which a third conductor layer is formed and a second main surface which is positioned on a side opposite to the first main surface and on which a fourth conductor layer is formed;
a first insulating layer covering the first main surface of the core layer and obtained by impregnating a core material with resin;
a second insulating layer covering the second main surface of the core layer and obtained by impregnating a core material with resin;
a through hole conductor penetrating the core layer and connecting a first feeding pattern included in the third conductor layer and a second feeding pattern included in the fourth conductor pattern;
a first via conductor penetrating the first insulating layer and connecting a third feeding pattern included in the first conductor layer and connected to the electronic component and the first feeding pattern; and
a second via conductor penetrating the second insulating layer and connecting the antenna pattern and the second feeding pattern, and
wherein the core layer is larger in thickness than the first and second insulating layers.

3. The antenna module as claimed in claim 2, wherein the through hole conductor and the first via conductor are provided so as to overlap the antenna pattern.

4. The antenna module as claimed in claim 2, wherein the core layer is larger in thickness than the electronic component.

5. The antenna module as claimed in claim 2,
wherein the third conductor layer further includes a first ground pattern provided so as to surround the first feeding pattern and overlapping the antenna pattern, and
wherein a second ground pattern included in the first conductor layer is connected to the first ground pattern through a third via conductor penetrating the first insulating layer.

6. The antenna module as claimed in claim 2, wherein the first and second via conductors have a filled-via structure.

7. The antenna module as claimed in claim 1, wherein the core substrate and the outermost insulating layer are smaller in thermal expansion coefficient than the resin layer.
